(19) United States
(12) Patent Application Publication
(10) Pub. No.: US 2014/0113136 A1
(43) Pub. Date: Apr. 24, 2014

(54) UNSEEDED SILICON CARBIDE SINGLE CRYSTALS

(71) Applicant: Charles Eric Hunter, Boone, NC (US)

(72) Inventor: Charles Eric Hunter, Boone, NC (US)

(21) Appl. No.: 14/139,616

(22) Filed: Dec. 23, 2013

Related U.S. Application Data
(63) Continuation of application No. 11/273,245, filed on Nov. 14, 2005.

(51) Int. Cl. C30B 29/36

(52) U.S. Cl. CPC C30B 29/36
USPC 428/402

(57) ABSTRACT

High volumes of relatively large, single crystals of silicon carbide are grown in a reactor from a point source, i.e., unseeded growth. The crystals may be grown colorless or near colorless and may be processed for many uses, including use as a diamond substitute for jewelry, as an optical element such as a watch face or a lens, or for other desired end uses.

### FIELD OF THE INVENTION

The invention relates to the production of silicon carbide (SiC) crystals. More particularly, the invention relates to the high volume production of relatively large, unseeded, synthetic single crystals of silicon carbide. These crystals may be processed for many uses, including use as a diamond substitute for jewelry, as an optical element such as a watch face or a lens, or for other desired end uses.

### BACKGROUND OF THE INVENTION

Since the Acheson process was developed by Edward Acheson in 1891, single crystalline silicon carbide has been manufactured in bulk for abrasive applications. The Acheson process, briefly stated, is the reaction of carbon (C) with silicon dioxide (SiO₂) to form SiC and carbon monoxide (CO). In a typical application of the Acheson process, a carbon source (graphite, rice hulls, etc.) and SiO₂ (sand) are loaded into an electric furnace that is heated to around 1697° C. A series of gas phase reactions set forth below occur to produce the bulk SiC:

C+SiO₂→SiO(g)+CO(g)

SiO₂+CO(g)→SiO(g)+CO₂(g)

C+CO₂→2CO(g)

2C+SiO→SiC+CO(g).

Further details of the Acheson process may be found in Acheson's U.S. Pat. Nos. 492,767 and 615,648, and in “Acheson Process”, Philip J. Guichelaar, in Carbide, Nitride and Boride Materials Synthesis and Processing, Publisher Chapman & Hall, London, UK, 1997, 115-129.

SiC crystals can form in more than 140 atomic arrangements (polytypes); all of these are extremely hard (varying between 9.2 and 9.5 on the Mohs scale—where diamond is 10). SiC is the third hardest material, eclipsed only by boron carbide and diamond (single crystalline carbon). In addition, the refractive index of single crystalline SiC is slightly higher than diamond. Certain hexagonal polytypes of SiC have a wide enough energy band gap (the energy, measured in electron volts, |eV|, required to ionize an electron from the valence band to the conduction band) to transmit visible light. These polytypes, including 6H SiC (energy band gap 2.86 eV), transmit substantially all visible light when undoped (i.e., no, or very low, impurity level); because of the close match in refractive index to diamond these SiC polytypes internally reflect light with the same or greater brilliance when cut into traditional diamond gemstone shapes. In contrast, the cubic polytype of SiC has an energy band gap of 2.4 eV, therefore absorbing part of the visible light spectrum and appears yellow when undoped.

For abrasive applications, there has never been a need for SiC crystals that can internally reflect light. In fact, crystals for abrasive applications, produced via the Acheson process, are heavily contaminated with other atomic species and are, therefore, black in color and do not internally transmit light.

In 1954, Jan Anthony Lely, a scientist at Phillips, a Netherlands-based company, developed a process for growing small single crystals of silicon carbide by the sublimation of SiC, where the SiC feed material was made using the reaction of precursor materials Si0₂+3C→SiC+2CO at 1800 degrees C., to form small flat SiC crystals for use in semiconductor applications. (See U.S. Pat. No. 2,854,364.) These crystals are known as Lely crystals. Because the Lely process utilized nucleation at a point source and did not use seeds, crystalline defects, such as those found in seeded growth, were not transferred into the growing crystal. Therefore, notwithstanding all of the progress made in SiC crystal growth during the last 50 years, Lely crystals remain the lowest defect crystals produced.

The Lely process design, however, did not allow for a large amount of precursor material and did not provide for sufficient effusion around the growing crystal interface to sweep impurities and clusters of nonstoichiometric SiC species from the growth interface. In addition, the Lely process used a very high temperature (2560 degrees C.) and did not utilize a thermal gradient to drive mass transport; thus, the process time was short, approximately 5 to 6 hours, and yielded only small, low aspect ratio (i.e., flat) SiC crystals. However, because the Lely crystals grew from a point source (unlike seeded growth techniques—e.g., Tairov, Siemans, Davis), they contained a very low dislocation density and no micropipe defects as were present in the later seeded techniques.

Later work by Chelnokov et al. in 1997 provided some effusion at the crystal growth interface, but without a significant temperature gradient to drive mass transport. This work was, however, important in that it did conclusively verify the significance of point source SiC growth versus seeded SiC growth. The Lely crystals grown by Chelnokov's group were thin, flat crystals that were relatively large in diameter (up to almost two cm) and contained a far lower defect density than today's state-of-the-art seeded SiC crystals. See “Growth and Investigation of the Big Area Lely-Grown Substrates”, Alexander A. Lebedev, et al, Materials Science & Engineering, Publisher Elsevier Sciences, 1997, 291-295.

Thus, while significant strides have been made in producing single crystalline SiC by both seeded and unseeded (point source growth) techniques, there remains an acute need for a process and apparatus that will permit high volume production of relatively large, unseeded single crystals of SiC.

As described in U.S. Pat. Nos. 5,723,391 and 5,762,896, gemstones, including colorless and near colorless gemstones, have been fashioned from silicon carbide material since the mid 1990's. However, thus far the silicon carbide material has been grown by seeded sublimation processes. The availability of unseeded crystals having sufficient size and optical properties would greatly benefit this industry by driving down the cost of the silicon carbide material from which the gemstones are fashioned, and providing the prospect of having the top (or “table”) of the gemstone be the atomically smooth, as-grown basal plane of the unseeded crystal.

### SUMMARY OF THE INVENTION

The present invention allows the high volume production of relatively large, unseeded, synthetic single crystals of 6H and other polytypes of SiC, generally with energy band gaps equal to or greater than 2.86 eV. These crystals may be produced with desired properties, including light transmission properties, that are desirable for many commercial applications, and in desired colors, for example, colorless or near-colorless (intrinsic), blue, green and red.

In one aspect, the present invention may be defined as a colorless or near colorless synthetic, unseeded single crystal of SiC having a thickness greater than about 0.25 cm as measured in a direction perpendicular to the basal plane of the crystal. These crystals may be fabricated into various types of gemstones, or used to produce other end products such as watch faces and lenses.

In another aspect, the invention may be defined as a synthetic, unseeded single crystal of SiC having a thickness greater than about 0.25 cm as measured in a direction perpendicular to the basal plane of the crystal, and having the ability to transmit visible light. This crystal may be produced with lattice defect density and impurity level characteristics sufficient to render the crystal colorless or near colorless when grown without intentionally added dopants.

In another aspect, the invention may be defined as a diamond gemstone substitute comprising a single crystal of synthetic, unseeded, colorless or near colorless SiC polished to a degree sufficient to permit the introduction of light into the gemstone for internal reflection from inside the gemstone. Such a gemstone may have any one of many gemstone shapes, including round brilliant cut and emerald cut. The table of these gemstones may be the basal plane of the SiC crystal.

In another aspect, the invention may be defined as a process for producing large, synthetic, unseeded single crystals of SiC. This process includes loading a reactor with particulate SiC precursor material predominately formed of particles with a size greater than about 0.05 inches, and thereafter heating the SiC precursor material to a temperature in the range from about 2280° C. to 2525° C. while maintaining a preferentially cooled unseeded crystal growth interface at a lower temperature than the temperature of the precursor material to provide a temperature gradient from the precursor material to the crystal growth interface sufficient to create mass transport to the interface, and while maintaining the precursor material temperature and the temperature gradient for a period of time sufficient to produce, at the crystal growth interface, unseeded single crystals of silicon carbide having a thickness greater than about 0.25 cm as measured in a direction perpendicular to the basal plane of the crystal.

In another aspect, the invention may be defined as a precursor material for use in the production of SiC single crystals. The precursor material includes particulate polycrystalline SiC predominately formed of particles having a size greater than about 0.05 inch and having less than about one part per million (ppm) metallic impurities.

In another aspect, the invention may be defined as a process for preparing polycrystalline SiC precursor material for use in the production of SiC single crystals. This process includes heating a mixture of Si powder and C powder in a two-phase heating cycle comprising an initial phase carried out in a temperature range from about 1000° C. to about 1410° C., followed by a second phase carried out above about 1420° C.

The process for preparing polycrystalline SiC precursor material may be more particularly defined as a process that includes heating, in an inert atmosphere, a mixture of semiconductor grade Si powder and C powder having a particle size range on the order of about 0.005 to about 0.070 inch in a two-phase heating cycle comprising an initial phase carried out in a temperature range from about 1300° C. to about 1410° C. for a period on the order of about 1 to about 24 hours, followed by a second phase carried out in a temperature range from about 1500° C. to about 1700° C. for a period on the order of about 4 to about 16 hours.

In another aspect, the invention may be defined as a reactor for growing synthetic, unseeded single crystals of silicon carbide. The reactor includes an outer annular zone for containing a charge of SiC precursor material; an intermediate annular zone concentric with the outermost zone, the intermediate zone serving as the primary growth chamber for the reactor; a central zone inside the intermediate zone, the central zone serving as a secondary growth chamber for the reactor; the outermost zone and intermediate zone being separated by a wall structure that is porous to constituent vapor species such as SiC, SiC₂, Si₂C, C and Si that emanate from the SiC precursor material during crystal growth operations; and the intermediate zone and the central zone being separated by a wall having effusion openings that permit the constituent vapor species to flow into the central zone. During operation of this reactor for SiC crystal growth, the SiC precursor material is heated to a temperature sufficient to produce the constituent vapor species and the wall separating the intermediate zone and central zone is maintained at a temperature lower than the precursor material to create a temperature gradient that facilitates mass transport of the constituent vapor species into the primary and secondary growth zones, and wherein the total vapor pressure of the constituent vapor species in the primary growth chamber is greater than the total vapor pressure of the constituent vapor species in the secondary growth chamber

In another aspect, the invention may be defined as a wall structure for use in a SiC crystal growth reactor to contain SiC precursor material that is heated to a temperature where it produces constituent vapor species such as SiC, SiC₂, Si₂C, C and Si. The wall structure separates the precursor material from a crystal growth chamber and is porous to the constituent vapor species so that the species can move through the wall structure to the growth chamber. The wall structure includes an outer wall remote from the crystal growth chamber; an inner wall adjacent to the crystal growth chamber, the inner wall being spaced apart from the outer wall to create a gap therebetween; carbon powder filling at least a portion of the gap between the inner wall and outer wall; and openings formed in both the inner and outer walls to permit the constituent vapor species to move through the wall structure to the crystal growth chamber while the carbon powder within the wall structure serves as a high surface area carbon interface to preferentially encourage recombination of the vapor species to SiC, SiC₂ and Si₂C while the species are flowing through the wall structure. The inner and outer walls may be formed as concentric cylinders of graphite material.

### BRIEF DESCRIPTION OF THE DRAWINGS

Some of the features of the invention having been stated, other features will appear as the description proceeds, when taken in connection with the accompanying drawings, in which—

FIG. 1 is a flow chart showing steps in an overall process for producing high volumes of unseeded, synthetic SiC single crystals according to embodiments of the present invention.

FIG. 2 is a side section view of a crucible in which a high purity mixture of Si powder and C powder is heated to produce polycrystalline SiC precursor material.

FIG. 3 is a side section view of a reactor into which the precursor material is loaded and in which SiC single crystals of the invention are produced.

FIG. 4 is an enlarged side section view of a portion of an alternative embodiment for the porous wall structure that separates the chamber holding the SiC precursor material from the crystal growth chamber.

### DETAILED DESCRIPTION OF THE INVENTION

While the present invention will be described more fully hereinafter with reference to the accompanying drawings, in which aspects of the preferred manner of practicing the present invention are shown, it is to be understood at the outset of the description which follows that persons of skill in the appropriate arts may modify the invention herein described while still achieving the favorable results of this invention. Accordingly, the description which follows is to be understood as being a broad, teaching disclosure directed to persons of skill in the appropriate arts, and not as limiting upon the present invention.

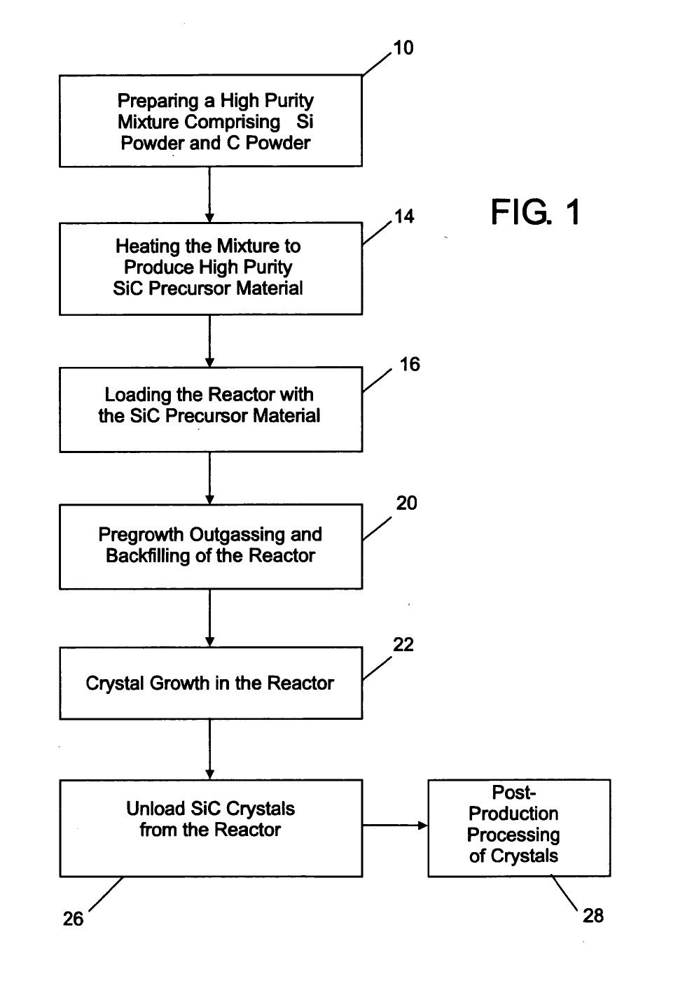

Referring to the drawings, and particularly to FIG. 1, there is shown a flow chart describing an overall operation that produces SiC single crystals according to an embodiment consistent with the present invention.

Initially, a high purity mixture comprising Si powder and carbon (C) powder is prepared (Block 10).

Next, the high purity mixture is heated under process parameters that produce high purity polycrystalline SiC precursor material (Block 14).

Next, the polycrystalline SiC precursor material is loaded into a reactor (Block 16).

Next, the reactor is subjected to pre-growth outgassing and backfilling to provide an ultraclean atmosphere suitable for growth of the single crystalline SiC (Block 20).

Next, the crystal growth process is carried out in the reactor (Block 22).

Following crystal growth, the next step is to unload the large volume of low defect density, high purity single crystals of unseeded SiC from the reactor (Block 26).

Last, as a post-production step, the single crystalline SiC may be processed for end uses (Block 28).

The description will now turn to a detailed description of the above process steps, the apparatus used to carry out the process steps, the crystals grown by the process and end products that may be fabricated from the crystals.

Producing a High Purity Mixture of Si Powder and C Powder (which is Later Reacted to Produce the Precursor Charge for the Reactor)

The initial step in the overall process illustrated in FIG. 1 is the production of a Si powder and C powder mix. In certain embodiments consistent with the invention, the Si and C powders that form the mix are semiconductor grade. Preferably, the carbon powder is rendered fully cleaned by high temperature chlorine or fluorine processes known in the art. The Si and C powders are mixed on a roughly one-to-one atomic basis (roughly a 7:3 Si-to-C ratio by weight). A preferred particle size for both the Si and C powders may be on the order of about 0.01 to about 0.02 inch diameter, with a particle size range on the order of about 0.005 to about 0.070 inch being deemed suitable. The mixing of the two powders should be performed in a high purity environment, preferably using a mechanical mixer that provides an inert atmosphere in its mixing chamber. A suitable mechanical mixer is a plastic rolling mill (not shown), operating at 10 to 80 revolutions per minute, and the inert atmosphere in the mixing chamber may be argon at, for example, 99.9999 purity. The rolling mill or other mechanical mixer may be used to mix the Si and C powders for an extended period of time, for example, a mixing time on the order of about 10 hours, with a mixing time of about 4 to about 30 hours being deemed suitable.

Utilizing the Mixture of Si Powder and C Powder to Produce Crystalline SiC Precursor Material that can be Loaded into the Reactor

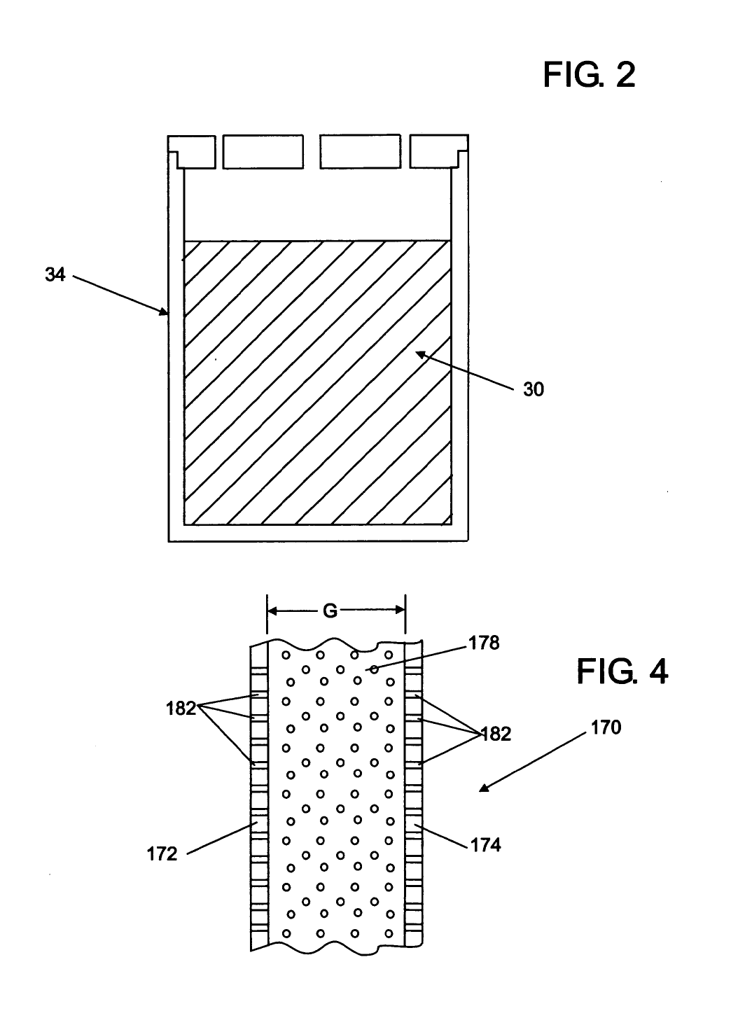

The mixture of Si and C powders, produced in the manner described above, is next heated under process parameters that produce polycrystalline SiC precursor material suitable for use in connection with this invention. To this end, in one representative way of carrying out the invention, the Si and C powder mixture 30 is loaded into a crucible 34 (FIG. 2). The crucible preferably is nonreactive, for example, a high purity carbon crucible. The crucible is first outgassed to achieve a suitably pure atmosphere, followed by a heating cycle that produces the polycrystalline SiC precursor material from the reaction of the powders (Si+C→SiC). To this end, outgassing of the crucible may be achieved in any suitable manner, for example, by a cycle utilizing a high purity argon (99.9999) atmosphere and repeated evacuation of the crucible by a mechanical pump. In one preferred outgassing procedure, the crucible with the mentioned argon atmosphere at, for example, about 800 torr may be heated to a temperature on the order of about 100° C. to about 1300° C., with about 300° C. being preferred, and then outgassed by a mechanical pump to 10⁻³ torr—with this procedure being repeated multiple times to assure sufficient outgassing.

In accordance with one embodiment consistent with the invention, following outgassing, a two phase heating cycle is carried out to produce the crystalline SiC precursor material. An initial phase of the heating cycle may take place at a temperature in the range of about 1000° C. to about 1410° C., with a more preferred range of about 1300° C. to about 1410° C., and most preferred with a temperature on the order of 1380° C. At about 1380° C., in a high purity inert atmosphere, the initial phase of the heating cycle may be carried out in about 1 hour to about 24 hours, with a more preferred duration of about 4 to about 12 hours and with an initial phase duration on the order of about 8 hours being preferred.

Following the initial phase, the heating cycle moves to a second stage for a time period on the order of about 4 to about 24 hours, with a time period on the order of about 12 hours being preferred. The second phase is carried out at a temperature above the melting point of Si, i.e., above about 1420° C., with a temperature range of about 1500° C. to about 1700° C. being preferred, and a temperature on the order of about 1600° C. being most preferred. The second phase is concluded by reducing the temperature of the crucible to near room temperature over a linear ramp and then turning off the power.

It will be appreciated that the initial phase of the above-described heating cycle serves as a “yield step”, i.e., during the initial phase most of the Si reacts with the available C. During this initial phase the reaction Si+C→SiC takes advantage of the very high surface energy to drive what is primarily a vapor-based mass transport reaction. A high chemical gradient exists during the initial phase that drives the reaction Si+C→SiC, a reaction that has a very low free energy of formation. This reaction is clearly favored because SiC is more thermodynamically stable at and around 1380° C. than the constituents that are present. Therefore, during the initial phase of the heating cycle as carried out according to certain embodiments of this invention, the formation of SiC is highly favored and the production of relatively large, pure precursor material particles is made possible.

It will be appreciated that during the second phase of the heating cycle, the remaining free Si melts and reacts with available C, with some portion of the Si carried away as a vaporized off gas. As a result, at the end of the second phase, substantially all of the Si and C have reacted to form pure SiC, with very little free Si remaining.

After crucible 34 has cooled, the crystalline SiC precursor material is removed from the crucible and broken into small pieces, preferably into pieces with a size range on the order of about 0.05 inch to about 0.20 inch. These crystalline pieces are preferably cleaned at this point, for example, by an acid bath. This procedure may be carried out by a bath in a mixture of hydrofluoric acid and hydrochloric acid, coupled with mechanical stirring. The bath may be carried out over a period of hours, for example, on the order of 5 to 10 hours, followed by drying, preferably in an inert atmosphere. The dried material is next screened to obtain precursor material in the desired particle size range. The particulate polycrystalline SiC is predominately formed of particles having a size greater than 0.05 inch. A particle size range of about 0.05 to about 0.20 inches is preferred, with a range of about 0.05 to about 0.10 inches being most preferred.

The precursor material, so produced, generally has the physical characteristics of a gray sand. The purity level may be defined as being less than one part per million (ppm) metallic impurities. The large size of the precursor material particles is important because the present invention, in its preferred embodiments, is carried out with long run times during the production of the crystals, necessitating large-particle precursor material that will last through the run.

### The Reactor

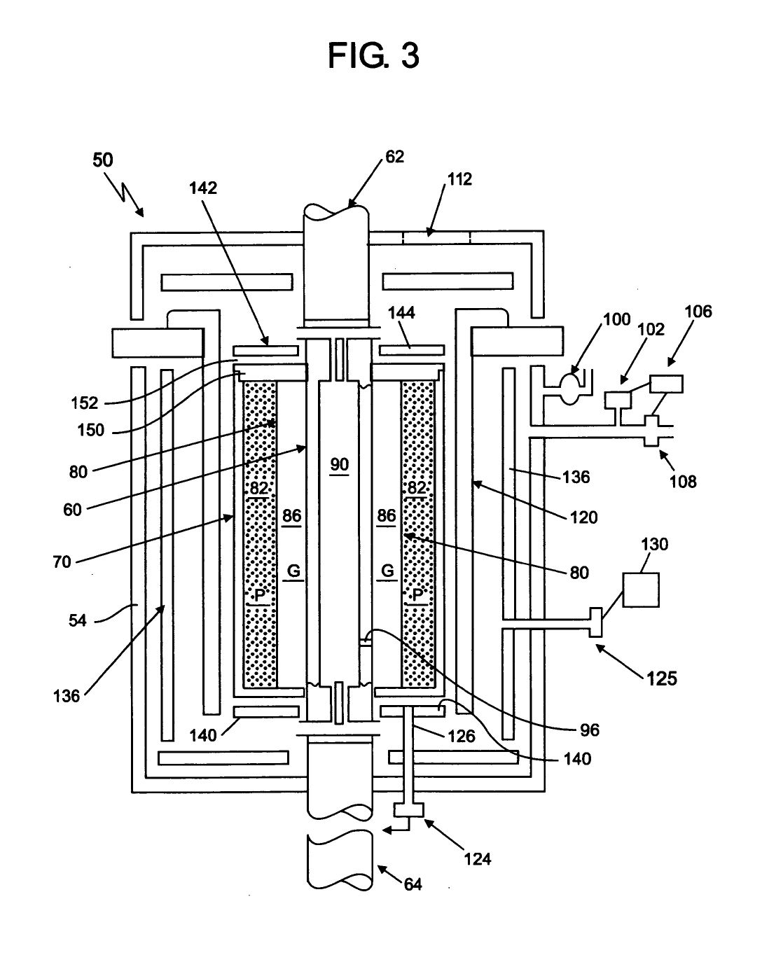

Before continuing the description of the production process, a representative reactor 50 (FIG. 3) will now be described. Reactor 50 is utilized to receive a charge of SiC precursor material and, by a non-seeded (point source) growth operation, produce a high volume of unseeded single crystals of SiC of the invention.

Reactor 50 includes a water-cooled stainless steel jacket 54 that encases the reaction zone and provides heat transfer capabilities for cooling. A high purity, carbon impregnated, high density graphite (e.g., POCO graphite) hollow tubular structure or rod 60 is centrally, vertically located in the reactor and is threadably secured at its upper and lower ends to tungsten support rods 62 and 64, respectively. Rods 62, 64 are cooled by circulating water (not shown) in a manner well known in the art, and serve to cool rod 60 from its ends during crystal growth operations.

Also vertically oriented is a high purity graphite cylinder 70 concentric with rod 60. Disposed between rod 60 and cylinder 70 is a second concentric cylinder 80 formed of material providing a porous high surface area carbon interface, as described below. Together, members 60, 70 and 80 form an outer annular chamber 82, an intermediate annular chamber 86 and a central chamber 90 formed by the hollow central portion of rod 60.

Annular chamber 82 receives the reactor's charge “P” of SiC precursor material as shown in FIG. 3. Intermediate annular chamber 86 is the primary growth zone “G” in which the single crystalline SiC is primarily grown. Central chamber 90 serves as a path accommodating the flow of effusion gas during crystal growth, with the effusion gas being supplied from chamber 86 to chamber 90 by effusion holes 96, only one of which is shown in FIG. 3. It will be appreciated that rod 60 includes multiple effusion holes 96 extending throughout the height of rod 60 and around its perimeter. In certain embodiments consistent with the invention, effusion holes 96 have diameters in the range from about 0.005 inch to 0.010 inch. Further details of the structure and function of chambers 70, 80 and 90 will be set forth later in the description, following a description of the other structured elements of reactor 50.

Reactor 50 includes a means for injecting high purity argon into the reactor via mass flow controller 100, with the argon pressure controlled via a capacitance manometer 102 and with a controller 106 controlling a gate valve 108 at a desired pressure, for example, at certain times during the growth cycle, 5 torr.

Reactor 50 includes a blow-off relief mechanism. In the illustrated embodiment, this mechanism takes the form of a 10-inch vented blow-off disc 112 set at an appropriate blow-off pressure, for example, 1400 torr.

Reactor 50 further includes a cylindrical, high purity graphite resistance heating element 120 that surrounds cylinder and provides uniform heating to the crucible enclosing chambers 82, 86, 90. Current supplied to heating element 120 during growth is controlled by a control system including an optical pyrometer 124 that is attached sited through a graphite tube 126.

For pre-growth outgassing, argon is injected into the reactor via a mass flow controller. In this regard, pre-growth current levels required for heating element 120 (from approximately 800° C. to 2450° C.) are taken before each run and stored in a look-up table in computer 130 in a manner well known in the art of producing crystalline semiconductor materials.

Reactor 50 also includes heat shields that protect the reactor. The heat shields are shown as vertical heat shield 136 that surrounds heating element 120, lower heat shields 140 and upper heat shields 142 and 144.

It will be appreciated that the top 150 of the crucible enclosing chambers 82, 86, 90 may be formed of a suitable material, such as POCO impregnated graphite. A support 152 for heat shield 142 is disposed between top 150 and shield 142. Support 152 may be formed of structural graphite, for example, a structural graphite manufactured by Carbonne Company of France.

Loading the Reactor with SiC Precursor Material

In order to load the SiC precursor material into the reactor, the reactor top 150 is lifted to create access to annular chamber 82. Chamber 82 is then filled to a desired level with SiC precursor material, preferably substantially completely filling the chamber. In certain embodiments consistent with the invention, the precursor material is produced by the process described above in conjunction with the crucible of FIG. 2. However, in other embodiments consistent with the invention, the precursor material may be produced by a different process, or take a different form.

### Pre-Growth Outgassing and Backfilling of the Reactor

Prior to the growth cycle, the entire atmosphere of reactor 50 is subjected to a series of outgassing and backfilling operations to create a high purity environment for crystal growth.

In one embodiment consistent with the invention, outgassing occurs over a number of hours at elevated temperature with a continuous flow of inert gas through the reactor. To this end, a suitable outgassing procedure is to heat the reactor via heating element 120 to a temperature in the range of about 100° C. to about 1200° C. for a period of one to three hours at a reduced pressure on the order of 10⁻³ to 30 torr, with a flow of inert gas through the reactor in the range of about 0.1% to 3.0% of the furnace volume per minute. In one particular preferred procedure, the temperature in reactor 50 is raised to approximately 800° C. in 3 hours and held at that temperature for hours with high purity argon flowed through the reactor at 0.5% of the furnace volume per minute, all at a pressure of approximately 1 torr. During this outgassing procedure, sufficient water is circulated through reactor jacket 54 to maintain desired temperatures throughout the system. The controls and other equipment necessary to achieve the outgassing steps described herein are well known in the art of producing crystalline semiconductor materials and, therefore, have not been described in complete detail.

Following each outgassing cycle, the reactor is backfilled with a high purity gas, for example, argon, which can be carried out at a pressure of about 800 torr.

The above process of outgassing followed by backfilling may be repeated three to five times.

### Crystal Growth in the Reactor

Following outgassing and backfilling, the reactor pressure is reduced, for example, to about 5 torr, and the crystal growth cycle begins.

It will be appreciated that the structure and operation of reactor 50 are designed to optimize conditions conducive to the growth of a high volume of relatively large, thick unseeded, synthetic SiC single crystals in each run. In this regard, in certain embodiments consistent with the invention, the SiC precursor material has a very high purity and a particle size distribution not previously associated with unseeded (point source) growth of SiC. These characteristics of the precursor material, coupled with the temperature gradient and chemical gradient provided by the system, sufficient effusion conditions, and other process conditions permit the use of large volumes of precursor material and long crystal growth run times, and the resultant production of very large quantities of unseeded, high purity SiC single crystals that not only grow out significantly along the basal plane, but also achieve significant thickness in the Z direction, i.e., the direction perpendicular to the basal plane.

In operation, it will be appreciated that the charge of SiC precursor material in chamber 82 is bound on the inside by the wall of cylinder 80. Cylinder 80 preferably is a porous, high surface area carbon interface that permits the species such as SiC, SiC₂, Si₂C, C and Si that are vaporized from the precursor charge to pass therethrough while presenting a carbon surface area to preferentially encourage the recombination of Si species with C. To this end, cylinder 80 may be formed of porous graphite having a suitable thickness to assure necessary structural integrity, for example, a thickness on the order of 0.125 inch. Thus, upon heating of the crucible to the run temperature, for example, 2400° C., species SiC, SiC₂, Si₂C, C and Si pass through the porous wall of cylinder 80 into the growth chamber 86 where the crystal grows primarily at growth interfaces on the outside wall of rod 60. The growth is encouraged by a thermal gradient on the order of about 5° C./cm to about 15° C./cm measured from outside wall 70 of chamber 82 to the primary crystal growth interfaces (nucleation sites) located on the outside of rod 60.

Crystal growth is also materially encouraged by the novel effusion of the crystal growth interface as provided by the invention. In this regard, multiple effusion holes 96 help to create a substantially constant and significant vapor velocity that sweeps away impurities and nonstoichiometric SiC species at the crystal growth interface. According to this aspect of the invention, effusion is preferably achieved by providing the above-described effusion holes 96 in the wall of tube 60, thereby providing a large number of spaced-apart effusion sites. This form of effusion is particularly effective as used with this invention for several reasons. First, each effusion hole provides a preferred site for nucleation. Second, undesirably high effusion gas velocities at the growing crystal interface do not occur because the effusion gases pass into and through a secondary chamber, inside rod 60, with its own partial pressure of the vapor species such as SiC, SiC₂, Si₂C, C and Si.

Referring to FIG. 4, there is shown an alternative structure (instead of porous graphite) for the cylindrical wall structure separating chamber 82 from chamber 86. As mentioned above, in certain embodiments consistent with the invention, this wall structure has the characteristic of providing a porous, high surface area, carbon interface that is presented to the SiC, SiC₂, Si₂C, C and Si species moving from chamber 82 to chamber 86. In the embodiment of FIG. 4, wall structure 170 is a multilayer structure comprising cylindrical outer wall 172 separated by a gap G from a concentric cylindrical inner wall 174, with at least a portion of the gap being filled with carbon powder 178, and preferably with substantially the entire gap being filled. Walls 172, 174 may be formed of graphite, for example carbon-impregnated graphite, with openings 182 formed therein to permit the species SiC, SiC₂, Si₂C, C and Si to move through to the crystal growth chamber G (86) while passing through the carbon powder to present the species a carbon source to preferentially encourage recombination of the vapor species to SiC, SiC₂ and Si₂C. Carbon powder 178 may have a particle size on the order of about 0.01 inch to about 0.03 inch. The openings 182 in walls 172, 174 should be smaller than the particle size of the carbon powder to prevent the carbon powder from passing therethrough. It will be appreciated that the wall structure encourages the above-described recombination of the vapor species not only because of the statistical advantage of the Si vapor coming into contact with many carbon atoms, but also because of the thermal gradient achieved because the carbon powder is slightly cooler than the vapor species (which are migrating from an area closer to heating element 120).

A second alternative embodiment (not shown) for the cylindrical wall structure is a single cylinder of graphite that has a density that permits diffusion of the constituent vapor species therethrough, thus allowing these vapor species to flow from chamber 82 to growth chamber 86.

At the beginning of the crystal growth cycle, the water cooling of tube 60 is significantly increased from that of the pre-growth outgassing cycle. At this time, the temperature of the crucible is increased over a linear ramp to a growth cycle temperature in the range of about 2280° C. to about 2525° C., with a temperature of about 2400° C. to about 2450° C. being preferred. At the growth cycle temperature, preferably there is a flow of inert gas (e.g., argon) at about 0.1% of furnace volume per minute, with the pressure decreased to 1 to 15 torr, preferably about 5 torr. This condition is held for about 10 to about 72 hours, preferably about 36 hours, as the growth cycle. At the end of the growth cycle, the heating element is turned off in a line ramp over about 4 hours and the reactor cools to near room temperature over 8 hours, while the pressure is raised to 760 torr, or atmospheric pressure. The as-grown crystals are then removed from reactor 50.

### Discussion of Theory

While the applicant does not wish to be bound by any particular theory, the following observations are offered:

1. The use of high purity (preferably less than 1 ppm metallic impurities) SiC precursor material in combination with the use of a high purity inert atmosphere and non-contaminating materials within the reactor, as described above and in Example I, below, produces crystal growth conditions conducive to the growth of very high purity crystals that, when desired, may be colorless or near colorless. These crystals may, when desired, be provided with intentionally added dopants that provide a desired color and shade of color to the crystal.

2. The nucleation of SiC at a point source (unseeded growth where defects in a seed crystal are not transferred to the growing crystal lattice) is believed to be the primary condition that encourages very low lattice defect densities (e.g., 10¹ to 10³ cm⁻²) and crystals without micropipes.

3. Process conditions consistent with the invention permit the SiC crystals, for example, hexagonal SiC crystals such as 6H, to be grown out along the basal plane to produce a significant area (i.e., up to one inch by one inch, and more) in the basal plane, while also producing substantial crystal thickness in the Z direction, i.e., a direction perpendicular to the basal plane. In this regard, the low energy of formation for growth in the basal plane encourages significant growth out along the basal plane, while the growth environment of the present invention simultaneously encourages significant growth in the Z direction, a direction of growth where the formation of SiC has a higher free energy of formation. One theory of operation is that embodiments of the present invention produce a more constant effusion and a high cooling of the crystal growth interface that encourages this type of growth.

4. The relatively large particle size of the SiC precursor material is believed to enhance the crystal growth process. In this regard, it is believed that smaller precursor material particle sizes, i.e., precursor material with a higher surface-area-to-volume ratio, when sublimed, produce the above-mentioned constituent vapor species in an undesirable ratio, particularly with respect to there generally being too much Si vapor at the outset of the growth cycle. On the other hand, the larger precursor material particles used in certain embodiments consistent with the invention are believed to result in the constituent vapor species having a more desirable stoichiometric ratio, particularly a stoichiometric ratio that does not have disproportionate amounts of Si vapor. Thus, it is believed that an initial Si vapor spike may be largely avoided and the ratio of constituent vapor species may be kept more consistent in the growth chamber throughout the growth cycle. A second, related advantage of the larger precursor material particle size is the fact that larger particles, when sublimed, simply last longer as an effective source of the desired constituent vapor species, resulting in the ability to have substantially longer crystal growth run times, and the ability to grow substantially larger, thicker crystals.

### DEFINITIONS

1. As used herein, the term “unseeded”, as applied to SiC crystals, refers to crystals that do not nucleate from a seed crystal.

2. As used herein, the term “colorless or near colorless” refers to the degree of color discernable when viewing a crystal of the invention or an end product made from such a crystal. More particularly, the term “colorless or near colorless” is used herein with reference to the Gemological Institute of America's color scale for grading the color of diamonds and encompasses gemstones below about J on the scale, generally from about D to about 1 on the scale.

3. As used herein, the term “synthetic” as applied to the SiC single crystals produced according to the invention, and the end products made therefrom, simply means that these articles are man-made, not naturally occurring.

4. The term “particle size” in reference to particulate matter is used herein in a conventional sense to refer to sizing by passing particulate matter through mesh screens.

5. As used herein, “effusion” refers to the flow of the constituent vapor species that emanate from the SiC precursor material as these vapor species flow along the thermal gradient to the crystal growth interface(s) (also referred to as nucleation sites) which, in the illustrated embodiments, are located primarily on hollow rod 60. Additionally, it will be noted that portions of rod 60 adjacent the effusion holes, as described above, serve as preferred sites for nucleation, in part because of the presence of a higher concentration of the vapor species, as well as the more favored chemistry present at these sites due to effusion sweeping away impurities and clusters of nonstoichiometric SiC species.

### SiC Gemstones and Other End Uses for the Unseeded SiC Single Crystals

The large size of the crystals of the invention as measured in the basal plane, coupled with the substantial thickness of the crystals as measured in a direction perpendicular to the basal plane, as well as the ability to grow the crystals colorless or near colorless, make the crystals ideal candidates for being fashioned into SiC gemstones, many of which may be marketed as diamond substitutes. More particularly, crystal thicknesses of about 0.25 cm and greater permit the fabrication of round brilliant cut gemstones of up to about 0.1 to 0.2 carat and more, crystal thicknesses of about 0.50 cm and greater can be fabricated into round brilliant gemstones of about one third to one half carat and more, and crystals of about 0.80 cm thickness and greater can be fashioned into round brilliant gemstones of about one carat and more. Furthermore, the fashioning of these gemstones may be facilitated by using the as-grown, atomically smooth basal plane as the primary flat face of the gemstone, with the remainder of the stone being faceted from the crystal material and thereafter polished. In the case of a round brilliant cut gemstone, the as-grown basal plane may be used as the table of the gemstone, with the remaining facets of the bevel and pavilion being faceted from the material. The basal plane may be left in its as-grown state, or polished, as desired. Other gemstone shapes, such as emerald cuts, may also be fashioned from the SiC material of this invention. Most of these shapes, particularly those shapes such as round brilliant cut and emerald cut that involve faceting, are polished to a degree sufficient to permit the introduction of light into the gemstone for internal reflection from inside the gemstone.

Unseeded SiC single crystals of this invention may also be processed into other end products, including other products that take advantage of the crystals' ability to transmit visible light. Crystals may be processed into optical products such as watch faces and lenses that have exceptional hardness and scratch resistance, as well as excellent optical properties. According to certain embodiments consistent with the invention, crystals that transmit light with wave lengths greater than 700 nm may be processed into such products as infrared scanner windows and windows used in infrared communications devices, e.g., infrared transmitters and receivers.

### Example I

35 kg of high purity Si and C powder mix is produced by mixing 28 kg of 0.01-0.02 inch particle size semiconductor grade silicon (99.9999) powder with 12 kg 0.01-0.02 inch particle size (99.9999) high purity carbon powder (cleaned via a high temperature chlorine or fluorine process), where the starting materials silicon and carbon are on a one-to-one atomic basis. The mixing is performed in a horizontal high purity plastic rolling mill (not shown) at 50 revolutions per minute for 10 hours, preferably in an inert atmosphere such as 99.9999 argon.

After mixing the powders, the mixture is placed in a crucible (FIG. 2) under a high purity argon 99.9999 atmosphere where it is heated to 300° C. and evacuated (outgassed) to 10⁻³ torr. The argon pressure is then increased to 900 torr over a 10 minute ramp. This cycle to 10⁻³ torr is repeated three times via a mechanical pump. Next is the first phase of the heating cycle where the mixture is heated to 1380° C. for 8 hours in a high purity carbon crucible, for example, crucible 34 of FIG. 2, using a high purity (99.9999) argon atmosphere at a pressure of 800 torr. Next is the second phase of the heating cycle where the temperature is held at 1630° C. for 16 hours. The temperature is reduced to near room temperature (power off) over an 8 hour linear ramp.

The SiC so produced is then broken into small pieces (less than 0.5 cm particle size) and placed in a solution of 50% hydrofluoric acid and 50% hydrochloric acid where it is mechanically stirred for 8 hours. The SiC is then removed under high purity argon and placed on an acid resistant plastic drying pan where the temperature is held at 60° C. for 8 hours. The material is then screened to obtain high purity SiC crystalline precursor material having a diameter of 0.05 to 0.20 inches.

The reactor used is of the design of reactor 50 of FIG. 3 with a crucible height (from top 152 down to the bottom of chambers 82, 86) of approximately 30 inches and a crucible diameter (the diameter of cylindrical wall 70) of approximately 18 inches.

Next, the yield (approximately 35 Kg) of high purity SiC polycrystalline precursor material is placed as charge P in chamber 82 inside the reactor as described above, bounded on the inside by high purity porous graphite tube 80 and on the outside by high purity carbon impregnated tube 70. Preferably, chamber 82 is filled to the top with approximately 1950 cubic inches of the precursor material at a packing density of about 50%.

Effusion is accommodated by high purity carbon impregnated hollow rod 60, which has a plurality of 0.005 to 0.010 inch diameter effusion holes 96 as shown in FIG. 3. Exit of effusion gases from tube 60 is accommodated by 0.25 inch holes (not shown in FIG. 3) located at each end of tube 60.

Power is supplied to graphite heating element 120 such that the temperature as measured by optical pyrometer 124 increases in a linear ramp to 800° C. in 3 hours while the pressure is reduced to 10 torr. This outgassing condition is held constant for 8 hours while mass flow controller 100 continues to supply high purity argon at a rate equal to 0.5% of the furnace volume per minute.

Next, there is an increase in the flow of water (at, for example 25 to 28° C.) to water-cooled tungsten rods 62, 64 that are connected to each end of graphite rod 60. The flow rate for the cooling water is automatically controlled by a water regulator (not shown) that is modulated to maintain a set point temperature as measured by optical pyrometer 124. A cooling water flow rate at this point in the cycle is on the order of 30 gallons per minute for a growth operation similar to that described in this Example I. Next, the internal temperature of the reactor (as measured by optical pyrometer 125, FIG. 3) is increased to 2450° C. in a linear ramp over a 3 hour period. Cooling of hollow rod 60 produces a temperature difference of about 50° C. between the rod and the precursor material, resulting in a temperature gradient in the range from about 5° C./cm to about 15° C./cm. The flow of argon is decreased to 0.1% of furnace volume per minute and the pressure is decreased to 5 torr. This condition is held for 36 hours as the crystal growth period or “run time”. Following this period, the heating element temperature is decreased to near room temperature (power off) in a linear ramp of 8 hours as the argon pressure is increased to 760 torr, or atmospheric pressure.

This crystal growth run yields approximately 1.5 kg of colorless to near colorless unseeded 6H SiC single crystals having thickness in the Z direction, perpendicular to the basal plane, ranging from 0.25 cm to 0.8 cm, and above.

### Example II

To produce other colors of SiC, the same conditions described in Example I are used except impurities (dopants) are intentionally added, as shown below, in amounts that vary depending on the shade of color desired.
1. Blue—Aluminum or Aluminum Carbide
2. Green—Nitrogen
3. Red—Beryllium.
   Preferably, the dopants are added during the production of the SiC precursor material by mixing the dopant materials with the Si and C powders or, in the case of nitrogen, adding N₂ gas to the reactor during precursor formation. General ranges for the amount of particular dopants to be incorporated into the crystal lattice to achieve desired colors and shades of color are known to those skilled in the art. For example, a blue crystal, having a relatively light shade so that it is capable of internally reflecting a significant amount of light, may incorporate approximately 7×10¹⁶ atoms of aluminum per cubic centimeter of crystal.

While the present invention has been described in connection with certain illustrated embodiments, it will be appreciated that modifications may be made without departing from the true spirit and scope of the invention.

1. A colorless or near colorless synthetic, unseeded single crystal of SiC having a thickness greater than about 0.25 cm as measured in a direction perpendicular to the basal plane of the crystal.

2-35. (canceled)
